(19) United States
(12) Patent Application Publication
(10) Pub. No.: US 2023/0063400 A1
(43) Pub. Date: Mar. 2, 2023

(54) LOW_POWERED MEMORY DEVICE AND METHOD OF CONTROLLING POWER OF THE SAME

(71) Applicant: METACNI CO., LTD., Seoul (KR)

(72) Inventors: Young Seung KIM, Seoul (KR); Min Chul JUNG, Seoul (KR); Scott Seung Moon YOO, Seongnam-si (KR)

(21) Appl. No.: 17/865,381

(22) Filed: Jul. 14, 2022

(30) Foreign Application Priority Data
Aug. 30, 2021 (KR) 10-2021-0114889

(51) Int. Cl. G11C 7/10; G11C 7/12; G11C 8/08; G11C 5/02

(52) U.S. Cl. CPC G11C 7/1039; G11C 7/12; G11C 7/1096; G11C 7/1093; G11C 8/08; G11C 5/02

(57) ABSTRACT

The memory device according to an embodiment may comprise a memory cell array in which memory cells of a latch structure are connected in a matrix form to word lines and bit lines and a peripheral circuit configured to supply a first voltage to the memory cells only in a developing section of a read operation for the memory cells and supply a second voltage which maintains data of the memory cells and lower than the first voltage in other sections. The peripheral circuit may be configured to supply the second voltage to the memory cells in all sections of a write operation for the memory cells.

### CROSS-REFERENCE TO RELATED APPLICATIONS

This application claims the priority benefit of Korean Patent Application No. 10-2021-0114889 filed on Aug. 30, 2021, which is incorporated herein by reference for all purposes as if fully set forth herein.

This application is one of the results of “Technology innovation development (R&D) for small and medium-sized enterprises” (Project No. 1425144583 (2020.09.21-2021.09.20), Project Name: “Development of Intelligent Stream Data Buffer SoC for small and medium-sized OLED panels” hosted by Ministry of SMEs (Small and Medium-sized Enterprises) and Startups (MSS) and Korean Technology and Information Promotion Agency for SMEs (TIPA) in Republic of Korea.

### BACKGROUND

### Field

This disclosure relates to a low powered memory device and a power control method, and more particularly to a method and device for controlling a cell voltage supplied to an SRAM cell array.

### Related Art

Memory for storing large amounts of data is broadly classified into volatile memory and non-volatile memory. DRAM and SRAM are volatile memories, and flash memory is non-volatile memory.

Among the volatile memories, the DRAM that stores bit data in capacitors has a simple cell structure and high degree of integration. However, it must periodically refresh cells so that electrons in the capacitors do not leak, so it is difficult to control data input/output.

On the other hand, the SRAM stores bit data in a complete latch structure of two pairs of inverters each of which consists of two transistors and which are connected in a symmetrical manner. So, the SRAM has a lower density compared to the DRAM, but has advantages in that data is continuously stored without refresh while power is being supplied and input/output of data is fast.

The characteristics of the DRAM that must be periodically refreshed are not suitable for low-power-oriented mobile devices, and it is not easy to safely manage data stored in the DRAM in a mobile environment. The SRAM is advantageous in the mobile environment from the viewpoint of low power and data stability. Because the SRAM is easy to control and easy to integrate with logic processes, there is a trend to use the SRAM in an embedded form in many products.

Meanwhile, it is necessary to increase the operating speed of the SRAM according to the high specification of the electronic devices incorporating the SRAM, and as the operating speed of the SRAM is increased, the current consumption of the SRAM increases. Accordingly, the importance of low-power design to reduce the current consumption of the SRAM is increasing.

### SUMMARY

The present disclosure has been made in view of the above circumstances. It is an object of the present disclosure to provide a memory device and a driving method for reducing the current consumption of an SRAM.

Another object of the present disclosure to provide a method of adjusting the operating voltage supplied to the memory cell of the SRAM without control from a host.

The memory device according to an embodiment of this disclosure may comprise a memory cell array in which memory cells of a latch structure are connected in a matrix form to word lines and bit lines and a peripheral circuit configured to supply a first voltage to the memory cells only in a developing section of a read operation for the memory cells and supply a second voltage which maintains data of the memory cells and lower than the first voltage in other sections.

The method of driving a memory according to another embodiment of this disclosure may comprise generating a control signal as second logic indicating generation of a second voltage which is supplied to memory cells of a latch structure and maintains data of the memory cells, checking whether an operation mode is a read mode of reading the memory cells, checking whether a current section is a developing section for charging or discharging bit lines connected to the memory cells when the operation mode is the read mode, generating the control signal as first logic indicating generation of a first voltage higher than the second voltage when the current section is the developing section; and changing the control signal from the first logic to the second logic when the developing section ends.

By supplying a normal cell voltage to a memory cell only in the developing section of the read operation to read data from the memory cell, and supplying a voltage lower than the normal cell voltage to the memory cell in other sections of the read operation, all sections of a write operation, and other operation modes, the voltage supplied to the memory cell can be lowered in all sections except for some sections of the read operation, and thus power consumed by the memory cell can be reduced.

In addition, the memory device can adjust itself without receiving, from a host, a control signal for adjusting the voltage supplied to the memory cell, and it is possible to reduce the number of control signals received from the host.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 shows a prior art of supplying a lowered cell voltage to a memory cell by lowering a normal cell voltage according to a retention signal transmitted from a host.

FIG. 2 is a timing diagram illustrating an embodiment of supplying a lowered cell voltage to a memory cell, but supplying a normal cell voltage only in a necessary section,

FIG. 3 is a diagram illustrating the relationship between a cell and a bit line in an operation of reading a memory cell of an SRAM.

FIG. 4 is a diagram illustrating the relationship between a cell and a bit line in an operation of writing a memory cell of an SRAM.

FIG. 5 shows a section in which a normal cell voltage is required in an operation of reading an SRAM memory cell.

FIG. 6 schematically shows functional blocks of a memory device according to an embodiment of this disclosure.

FIG. 7 shows timings of generating the control signal CTRL_VC for controlling a cell voltage.

FIG. 8 shows inputs and output of the block for generating the control signal CTRL_VC for controlling the cell voltage.

FIG. 9 is a flowchart illustrating an operation for generating the control signal CTRL_VC for controlling the cell voltage.

### DETAILED DESCRIPTION

Hereinafter, a memory device and a memory driving method according to the present disclosure will be described in detail with reference to the accompanying drawings.

Same reference numerals refer to substantially identical elements throughout this disclosure. In the following disclosure, if it is determined that a detailed description of a known function or configuration related to an embodiment of this disclosure may unnecessarily obscure the subject matter of this disclosure, the detailed description thereof will be omitted.

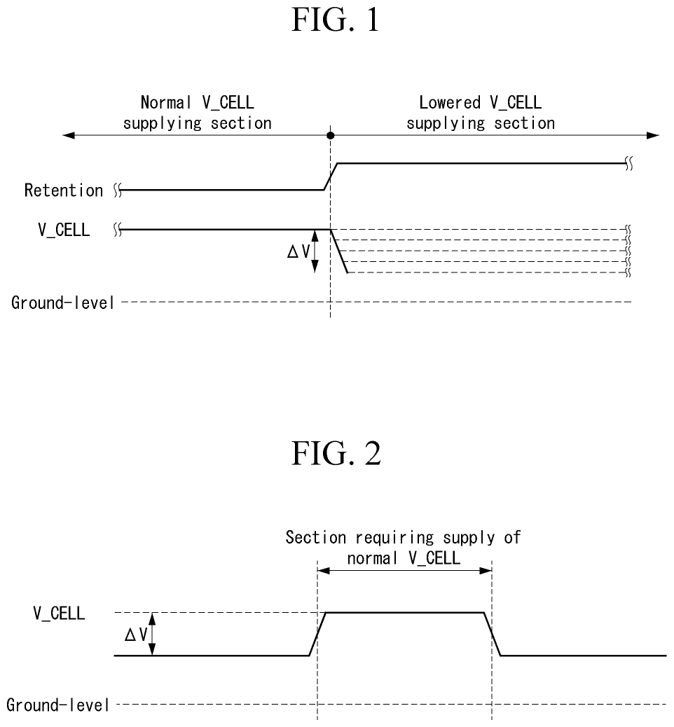

FIG. 1 shows a prior art of supplying a lowered cell voltage to a memory cell by lowering a normal cell voltage according to a retention signal transmitted from a host

A method of lowering power consumption by entering a retention mode during a section in which the memory cell is determined not to operate and lowering the cell voltage supplied to the memory cell is used.

The cell voltage supplied to the memory cell may be adjusted according to a signal transmitted from an external host, for example, a retention signal. The section of supplying a normal cell voltage (Normal V_CELL) and the section of supplying a lowered cell voltage (Lowered V_CELL) may be distinguished by using the retention signal. That is, a normal operating voltage of an SRAM cell is V_CELL, and when the retention signal is input from the host as, for example, high logic, the operating voltage of the cell may be lowered to the lowered V_CELL.

The lowered cell voltage may be set to the lowest voltage that allows the cell of the SRAM configured to include a latch to hold data. In FIG. 1, the normal operating voltage supplied to the SRAM cell is V_CELL, and when an operation mode is the retention mode in which the retention signal is sent from the host as, for example high logic, the cell voltage can be (V_CELL-ΔV) lowered by AV from V_CELL.

In the retention mode, the lowered level of the cell voltage supplied to the memory cell may be adjusted in several steps, and options may be provided to enable these multiple steps of the lowered level. The optimal level for reducing consumption current may be determined to be the lowest value among the levels in which the operation of the memory cell is not abnormal.

In sections in which the retention signal is not activated, a read operation and a write operation on the memory cell are performed. An effect of reducing current consumption or power consumption cannot be expected in areas or sections other than the section in which the retention signal is activated.

As described above, considering the sections in which the memory cell is driven, it is difficult to significantly reduce power consumption in the conventional method in which the cell voltage cannot be lowered in the sections in which the read operation and the write operation on the memory cell are performed.

FIG. 2 is a timing diagram illustrating an embodiment of supplying a lowered cell voltage to a memory cell, but supplying a normal cell voltage only in a necessary section.

In order to lower the power consumption, it is necessary to increase the sections for supplying a lowered cell voltage to the memory cell. To this end, the embodiments of this disclosure may distinguish the section in which a normal cell voltage must be supplied to a memory cell and the section in which a voltage lower than the normal cell voltage is supplied, supply the normal cell voltage only in the section in which the normal cell voltage is needed, and supply the lowered cell voltage in remaining sections.

That is, as shown in FIG. 2, the embodiment of this disclosure may set (V_CELL-ΔV) as the basic value of the cell voltage supplied to the cells of the SRAM, and supply V_CELL which is a normal cell voltage only in the section required for the normal cell voltage.

In addition, the memory device according to the embodiment of this disclosure may determine the section requiring the normal cell voltage and remaining sections by itself without receiving a separate control signal from a host and adjust the voltage supplied to the memory cell.

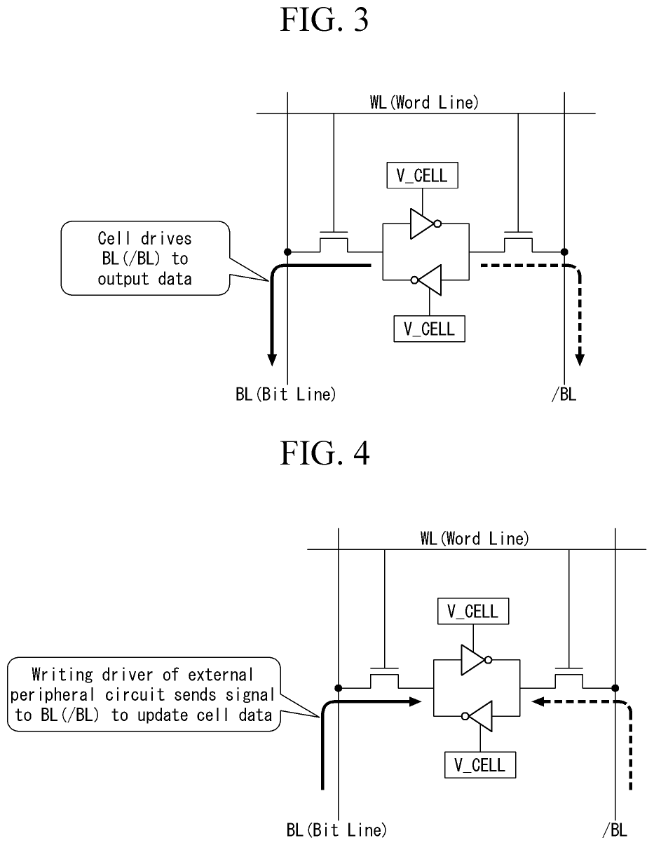

FIG. 3 is a diagram illustrating the relationship between a cell and a bit line in an operation of reading a memory cell of an SRAM, and FIG. 4 is a diagram illustrating the relationship between a cell and a bit line in an operation of writing a memory cell of an SRAM.

An embodiment of this disclosure may determine a section in which a normal cell voltage is supplied and a section in which a lowered cell voltage is supplied in consideration of the characteristics of a read or write operation to the SRAM memory cell.

The memory cell voltage is supplied to the transistor included in the memory cell. In the case of a read operation of an SRAM memory cell, as shown in FIG. 3, the transistor included in the memory cell drives data. In other words, the transistor charges or discharges the bit line BL and the inverted bit line/BL with the data stored in the latch of the memory cell. Accordingly, the driving capability of the memory cell affects the read operation of the sensing circuit that reads data carried on the bit line pair including the bit line BL and the inverted bit line/BL.

In the read operation of the memory cell, if the cell voltage supplied to the transistor included in the memory cell is lowered, data stored in the memory cell is not properly transferred to the bit line BL and the inverted bit line/BL, so that the driving ability for the bit line pair is degraded.

Accordingly, in a read operation the cell voltage of a normal level must be supplied to the memory cell.

On the other hand, in the case of the write operation of the memory cell, the driving transistor of the external region of the memory cell array, that is the peripheral circuit connected to the bit line BL and the inverted bit line/BL becomes a driving entity. That is, the driving transistor of the external circuit charges or discharges the bit line pair to write data to the memory cell.

While the cell voltage V_CELL is supplied to the memory cell, the V_PERI voltage is supplied to the transistor of the peripheral circuit separately from the memory cell. When writing data to the memory cell, it is advantageous for the cell voltage V_CELL to be lower than V_PERI supplied to the peripheral circuit.

Therefore, in the write operation, it is not necessary to supply the normal cell voltage V_CELL to the memory cell, and the cell voltage (V_CELL-ΔV) lowered enough to maintain data stored in the memory cell may be supplied.

In other words, it is possible to lower the level of the cell voltage over the entire sections in remaining operations other than the read operation.

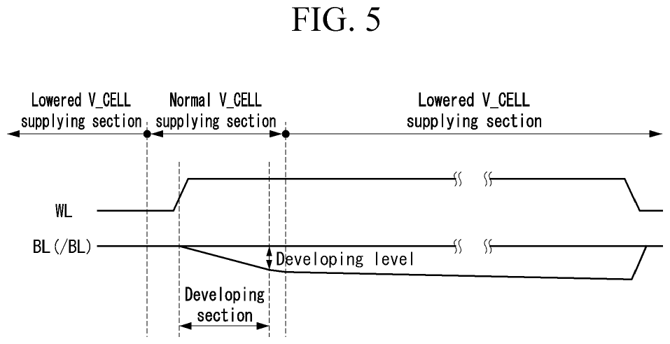

FIG. 5 shows a section in which a normal cell voltage is required in an operation of reading an SRAM memory cell.

There is no need to apply the normal cell voltage to all sections even in the memory cell read operation. After the bit line BL and the inverted bit line/BL are charged or discharged to a predetermined level with the bit data stored in the memory cell by developing, the input/output driving circuit of the peripheral circuit senses, amplifies, and outputs the data bits charged/discharged on each bit line pair.

After the bit line pair is charged or discharged above a predetermined level by developing, the potentials of the bit line and the inverted bit line can be maintained by the voltage V-PERI of the driving circuit during the sensing, amplifying and outputting, regardless of the cell voltage supplied to the memory cell.

That is, the cell voltage of the memory cell only participates in developing the bit line pair and does not play any role in reading the data charged in the bit line pair thereafter.

Accordingly, the embodiment of this disclosure, as shown in FIG. 5, may not supply the normal cell voltage V_CELL in over all sections even in a memory cell read operation, but supply the normal cell voltage V_CELL only in a developing section which is a section in which data is loaded on the bit line pair by charging and discharging the bit line pair and supply a lowered cell voltage in remaining sections.

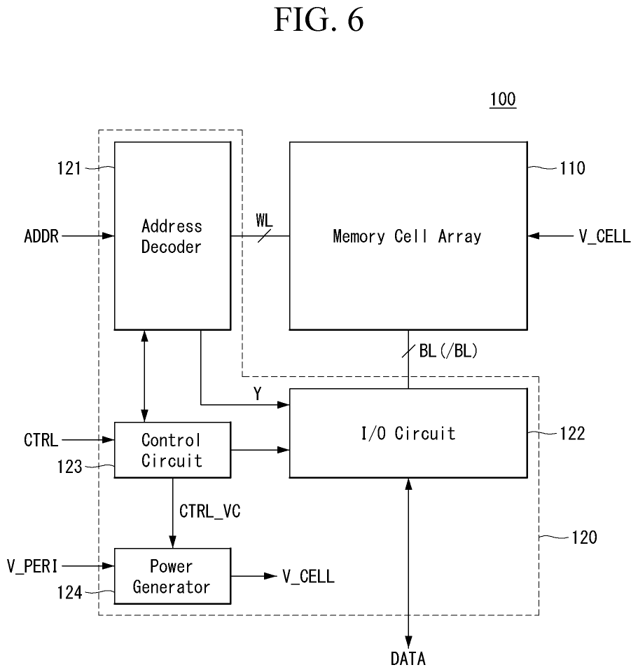

FIG. 6 schematically shows functional blocks of a memory device according to an embodiment of this disclosure.

The memory device 110 may comprise the memory cell array 110 including SRAM memory cells and a driving circuit or a peripheral circuit 120 configured to drive the memory cell array 110. The peripheral circuit 120 may include an address decoder 121, an input/output circuit 122, a control circuit 123 , and a power generator 124.

The address decoder 121 is configured to receive an address ADDR from a host, to be connected to the memory cell array 110 through word lines WL, and to drive the word lines WL under the control of the control circuit 123.

The address decoder 121 decodes a row address from which a word line WL to be driven is selected based on the received address ADDR. In addition, since the data read/write operation is performed in units of pages, the address decoder 121 decodes the column address Y for selecting the bit line pair BL(BL) included in the requested address ADDR and provides it to the input/output circuit 122 and/or the control circuit 123 so that the input/output circuit 122 can select a corresponding bit line pair.

The input/output circuit 122 receives or outputs data DATA to be written or read to/from the memory cell array 110, connects the bit line pair BL(/BL) selected by the colum address (Y[0]-Y[m]) provided by the address decoder 121 to the memory cell array 110, and performs the operation of writing or reading data to/from the memory cell array 110 under the control of the control circuit 123.

The input/output circuit 122 may comprise the data read circuit including the sense amplifier that detects and amplifies the data bit charged to the bit line, the data write circuit for charging the bit line with the data bits to be written to the memory cell, and the circuit configuration for equalizing and precharging the bit line pair BL(/BL).

The control circuit 123 is connected to the address decoder 121, the input/output circuit 122, and the power generator 124, and is configured to control the operation of the memory device 100, that is the operation of writing or reading data to/from the memory cell array 110.

That is, based on the control signal CTRL transmitted from a connected host, the control circuit 123 may determine the current operation mode (whether it is a write operation or a read operation), provide it to the input/output circuit 122, determine a timing to activate the word line WL and a timing to activate the bit line pair BL(/BL), and provide them to the address decoder 121.

In addition, the control circuit 123 may distinguish the read operation from the write operation and identify a developing section based on the control signal CTRL transmitted from the host and may generate a cell voltage control signal VC_CTRL to adjust the level of the cell voltage to be supplied to the memory cell array 110 based on the identification and provide it to the power generator 124.

The power generator 124 is configured to generate a plurality of voltages required for the operations of the memory cell array 110 and the peripheral circuit 120 by using an external voltage supplied to the memory device 100.

The power generator 124 may generate two or more different cell voltages according to the cell voltage control signal CTRL_VC provided by the control circuit 123 and supply them to the memory cell array 110. The power generator 124 may generates a normal cell voltage V_CELL in the developing section of a read operation, and generate a lowered cell voltage that is lower than the normal cell voltage in other sections of the read operation and in all sections of a write operation other than the read operation or a standby operation.

The voltage V_PERI required for the operation of the peripheral circuit 120 may be input from the host at a level higher than the normal cell voltage V_CELL supplied to the memory cell array 110, and supplied to the address decoder 121, the input/output circuit 122 and the control circuit 123.

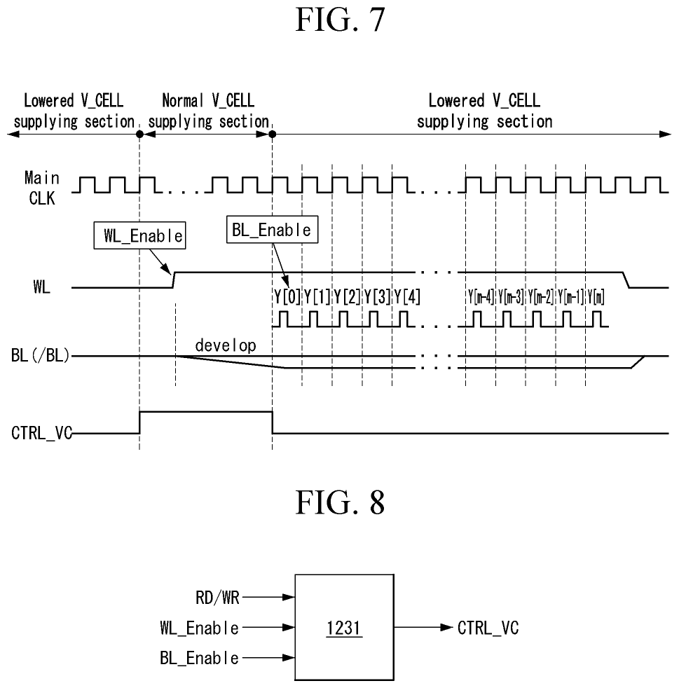

FIG. 7 shows timings of generating the control signal CTRL_VC for controlling a cell voltage, and FIG. 8 shows inputs and output of the block for generating the control signal CTRL_VC for controlling the cell voltage.

The control circuit 123 may distinguish whether a current operation mode is a read mode or a write mode RD/WR based on the control signal CTRL transmitted from the host and generate a word line enable signal WL_Enable activating a word line from which data is to be read and a bit line enable signal BL Enable sequentially activating bit line pairs (activating the first column line address Y[0]) in synchronization with a main clock (Main CLK) based on the control signal CTRL.

Also, in the read mode, the control circuit 123 may generate the cell voltage control signal CTRL_VC as first logic (high logic in FIG. 7) indicating the generation of the normal cell voltage V_CELL in synchronization with the word line enable signal WL_Enable, and generate the cell voltage control signal CTRL_VC as second logic (high low in FIG. 7) indicating the generation of the lowered cell voltage (V_CELL-ΔV) lower than the normal cell voltage V_CELL in synchronization with the bit line enable signal BL_Enable.

The section between a first timing synchronized with the word line enable signal WL_Enable and a second timing synchronized with the bit line enable signal BL_Enable corresponds to the developing section in which data of the memory cells, which is connected to the word line activated by the word line enable signal WL_Enable, are loaded on corresponding bit line pairs.

As shown in FIG. 8, the control circuit 123 may include a control signal generator 1231 that generates the cell voltage control signal CTRL_VC at the timing shown in FIG. 7 based on the signal RD/WR indicating the read/write mode, the word line enable signal WL Enable and the bit line enable signal BL_Enable.

The power generator 124 may generate the normal cell voltage V_CELL in the developing section of the read operation according to the cell voltage control signal CTRL_VC provided by the control circuit 123 and provide it to the memory cell array 110.

Considering the case in which the cell voltage supplied to the memory cell array 110 does not rise to the normal cell voltage during the developing section, a delay time (latency) may be increased from the bit line enable signal BL_Enable until a first column address Y[0] corresponding to a first bit line is activated.

Alternatively, the power generator 124 may adopt a method of rapidly raising a lowered cell voltage to the normal cell voltage, and in this case there is no need to delay the timing of generating the first column address Y[0].

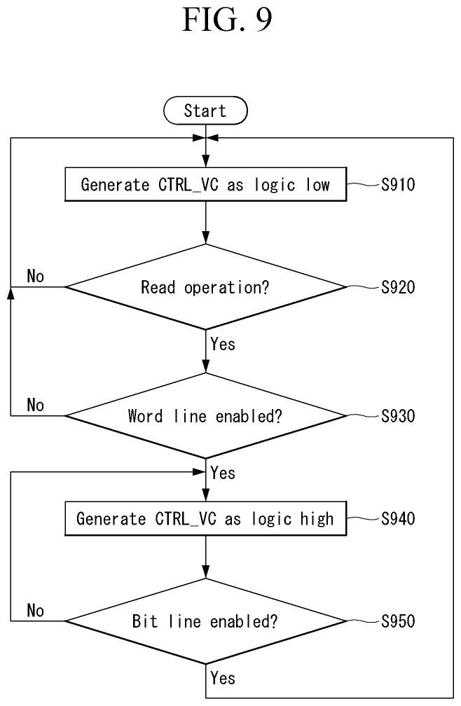

FIG. 9 is a flowchart illustrating an operation for generating the control signal CTRL_VC for controlling the cell voltage.

The control signal generator 1231 (hereinafter, simply referred to as the control circuit 123) generates the cell voltage control signal CTRL_VC as the low logic indicating to generate a cell voltage lower than the normal cell voltage V_CELL (S910).

The control circuit 123 checks whether a current operation mode is the read mode or the write mode (S920), and if it is not the read mode (NO in S920), it maintains the cell voltage control signal CTRL_VC as the low logic.

When the current operation mode is the read mode (YES in S920), the control circuit 123 checks whether the word line is activated by the word line enable signal WL_Enable (S930). The control circuit 123 maintains the cell voltage control signal CTRL_VC as the low logic when the word line is not activated (NO in S930), and generates the cell voltage control signal CTRL_VC as high logic indicating that the normal cell voltage V_CELL is generated when the word line is activated (YES in S930) (S940).

Thereafter, the control circuit 123 checks whether the first column address Y[0] is generated by the bit line enable signal BL Enable so the first bit line pair is activated (S950). When the first bit line pair is not activated (NO in S950), the control circuit 123 determines that the developing section is in progress and maintains the cell voltage control signal CTRL_VC as the high logic, and when the first bit line pair is activated (YES in S950), the control circuit 123 determines that the developing section is over and returns the process to step 5910 to generate the cell voltage control signal CTRL_VC as the low logic.

Like this, since the normal cell voltage is supplied to the memory cell only in the developing section of the read mode and the voltage supplied to the memory cell is lowered than the normal cell voltage in other sections of the read mode and other modes other than the read mode, the power consumed by the memory cell can be reduced.

In addition, since the operation of adjusting the cell voltage supplied to the memory cell can be performed by the memory device itself without the interference from the host, the number of control lines connected to the host can be reduced, thereby increasing the degree of freedom in designing the memory device.

Various embodiments of the memory device and the memory driving method of this disclosure will be simply and clearly described as follows.

The memory device according to an embodiment may comprise a memory cell array in which memory cells of a latch structure are connected in a matrix form to word lines and bit lines and a peripheral circuit configured to supply a first voltage to the memory cells only in a developing section of a read operation for the memory cells and supply a second voltage which maintains data of the memory cells and lower than the first voltage in other sections.

In an embodiment, the peripheral circuit may be configured to supply the second voltage to the memory cells in all sections of a write operation for the memory cells.

In an embodiment, the peripheral circuit may comprise a control circuit configured to a control signal for selecting one of the first voltage and the second voltage and a power generator configured to generate the first voltage or the second voltage according to the control signal.

In an embodiment, the control circuit may be configured to generate the control signal based on a first signal for enabling a word line and a second signal for enabling a bit line.

In an embodiment, the control circuit may be configured to generate the control signal as first logic indicating generation of the first voltage in synchronization with the first signal and generate the control signal as second logic indicating generation of the second voltage in synchronization with the second signal, in a state in which a signal indicating the read operation is received from a host.

In an embodiment, the power generator may be configured to adjust a level of the second voltage as one of multiple steps according to the second control signal of the control circuit.

The memory driving method according to another embodiment may comprise generating a control signal as second logic indicating generation of a second voltage which is supplied to memory cells of a latch structure and maintains data of the memory cells, checking whether an operation mode is a read mode of reading the memory cells, checking whether a current section is a developing section for charging or discharging bit lines connected to the memory cells when the operation mode is the read mode, generating the control signal as first logic indicating generation of a first voltage higher than the second voltage when the current section is the developing section; and changing the control signal from the first logic to the second logic when the developing section ends.

In an embodiment, the memory driving method may further comprise generating the control signal as the second logic when the operation mode is not the read mode.

In an embodiment, the generating of the control signal as the first logic may generate the control signal as the first logic in synchronization with a first signal for enabling a word line connected to the memory cells.

In an embodiment, the changing of the control signal may change the control signal from the first logic to the second logic in synchronization with a second signal for enabling the bit line.

In an embodiment, the memory driving method may further comprise generating a second signal for adjusting a level of the second voltage as one of multiple steps.

Throughout the description, it should be understood by those skilled in the art that various changes and modifications are possible without departing from the technical principles of the present disclosure. Therefore, the technical scope of the present disclosure is not limited to the detailed descriptions in this specification but should be defined by the scope of the appended claims.

What is claimed is:

1. A memory device, comprising:
a memory cell array in which memory cells of a latch structure are connected in a matrix form to word lines and bit lines; and
a peripheral circuit configured to supply a first voltage to the memory cells only in a developing section of a read operation for the memory cells and supply a second voltage which maintains data of the memory cells and lower than the first voltage in other sections.

2. The memory device of claim 1, wherein the peripheral circuit is configured to supply the second voltage to the memory cells in all sections of a write operation for the memory cells.

3. The memory device of claim 1, wherein the peripheral circuit comprises:
a control circuit configured to a control signal for selecting one of the first voltage and the second voltage; and
a power generator configured to generate the first voltage or the second voltage according to the control signal.

4. The memory device of claim 3, wherein the control circuit is configured to generate the control signal based on a first signal for enabling a word line and a second signal for enabling a bit line.

5. The memory device of claim 4, wherein the control circuit is configured to generate the control signal as first logic indicating generation of the first voltage in synchronization with the first signal and generate the control signal as second logic indicating generation of the second voltage in synchronization with the second signal, in a state in which a signal indicating the read operation is received from a host.

6. The memory device of claim 4, wherein the power generator is configured to adjust a level of the second voltage as one of multiple steps according to the second control signal of the control circuit.

7. A memory driving method, comprising:
generating a control signal as second logic indicating generation of a second voltage which is supplied to memory cells of a latch structure and maintains data of the memory cells;
checking whether an operation mode is a read mode of reading the memory cells;
checking whether a current section is a developing section for charging or discharging bit lines connected to the memory cells when the operation mode is the read mode;
generating the control signal as first logic indicating generation of a first voltage higher than the second voltage when the current section is the developing section; and
changing the control signal from the first logic to the second logic when the developing section ends.

8. The memory driving method of claim 7, further comprising:
generating the control signal as the second logic when the operation mode is not the read mode.

9. The memory driving method of claim 7, wherein the generating of the control signal as the first logic generates the control signal as the first logic in synchronization with a first signal for enabling a word line connected to the memory cells.

10. The memory driving method of claim 9, wherein the changing of the control signal changes the control signal from the first logic to the second logic in synchronization with a second signal for enabling the bit line.

11. The memory driving method of claim 7, further comprising:
generating a second signal for adjusting a level of the second voltage as one of multiple steps.
